(19) United States
(12) Patent Application Publication
(10) Pub. No.: US 2008/0204635 A1
(43) Pub. Date: Aug. 28, 2008

(54) Transparent, Conductive Film with a Large Birefringence

(76) Inventors: Andy Christopher Van Popta, Edmonton (CA); Kenneth David Harris, Edmonton (CA); Michael Julian Brett, Edmonton (CA)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 12/067,924

(22) PCT Filed: Sep. 22, 2006
(86) PCT No.: PCT/CA2006/001569

§ 371 Date: Mar. 24, 2008

Related U.S. Application Data
(60) Provisional application No. 60/719,905, filed on Sep. 23, 2005.

(51) Int. Cl. G02F 1/1335; H01B 1/00; B32B 3/26; H01L 21/385; H05B 33/06; G02F 1/13363

(52) U.S. Cl. 349/96; 252/500; 428/304.4; 313/504; 349/117; 438/565; 257/E21.468

(57) ABSTRACT

A thin film is formed by depositing a wide bandgap semiconductor material on a substrate by oblique physical vapor deposition to form a thin film structure. The thin film structure is transparent, electrically conductive, and birefringent.

### CROSS-REFERENCE TO RELATED APPLICATIONS

This application claims priority from U.S. provisional application Ser. No. 60/719,905, filed Sep. 23, 2005.

### BACKGROUND

Three common components in flat-panel displays are transparent electrodes, compensators, and liquid crystal (LC) alignment layers.

### Transparent Electrode

In many flat panel displays, an image is formed by an electrical signal or applied voltage that is capable of turning each pixel on and/or off. The voltage is typically applied between two electrodes, and depending on the type of display, one or both of the electrodes must be transparent so that the light that is emitted by the display can reach the user. The most familiar electrodes are made from metal, which is always opaque to visible light. A special class of materials, known as wide-bandgap semiconductors or transparent conducting oxides (TCOs), can be used to create transparent electrodes, the most popular of which is tin-doped indium oxide (ITO). ITO and other wide-bandgap semiconductors are normally formed on heated substrates using a thin-film deposition technique known as sputtering. The incidence angle of incoming flux is generally near to the substrate normal.

### Compensator

Birefringent coatings are often used as compensators in liquid crystal displays to improve contrast, gray-scale stability and display performance at wide viewing angles. For example, most uncompensated liquid crystal based displays work best when viewed straight on. When viewed from an angle, the contrast and quality of the image degrades, and the larger the viewing angle, the worse the performance of the display. To correct for viewing angle problems, birefringent thin films, or compensators, are added to the substrates of the LCD. A birefringent material has a refractive index that varies depending on the direction within the material. Currently, the industry standard is to use organic thin films consisting of reactive disc-shaped molecules that align themselves on a plastic substrate in a splayed configuration. These are UV cured, cut, and then laminated onto polarizer sheets, which is an expensive and time consuming process. The organic compensators are also susceptible to UV degradation and heat distortion.

### Alignment Layer

LCD uses an alignment layer to anchor the position of those LCs nearest to the substrate interface. Most often, a polymer film that has been rubbed with a velvet cloth is used as the alignment layer. This system has associated problems involving the generation of dust or fine particles and the discharge of static electricity into electronic components. Alternatively, a number of papers have been published on how obliquely-deposited silicon oxide films can also be used to achieve the same planar alignment of LCs obtained using rubbed polymer films.

### SUMMARY

According to one embodiment, there is provided a thin film microstructure, comprising a substrate and a film of vapor deposited wide bandgap semiconductor material, such as a transparent conductive oxide, extending in distinct columns from the substrate. According to another embodiment, the thin film microstructure comprises a film of oblique physical vapor deposited wide bandgap semiconductor material, such as a transparent conductive oxide on a substrate. The film may be transparent, electrically conductive, and birefringent. The transparent conductive oxide may be a metal-doped oxide selected from a group consisting of: In₂O₃, SnO₂, ZnO, Ga₂O₃, CdO, and combinations thereof. The wide bandgap semiconductor material may be deposited at an angle within 10° of the angle yielding the maximum birefringence, or at an angle between 20° and 89°, the angle being from the normal of the substrate on which the thin film is formed. The distinct columns may comprise vertical posts, leaning posts, vertical fan-like plates, leaning fan-like plates, helical structures, leaning helical structures, square spirals, chevrons, C-shapes, S-shapes, or columns where the physical cross-section varies in size. The distinct columns may have three principal indices of refraction, wherein the index of refraction is largest in a direction parallel to a central axis of the distinct columns. The film may comprise multiple layers.

According to another embodiment, the thin film microstructure is in combination with carbon-based films and an electrode to form an organic light emitting diode. According to another embodiment, the thin film microstructure is in combination with a liquid crystal layer and a reflective substrate to form a liquid crystal on silicon display.

According to another embodiment, a liquid crystal display or a liquid crystal pixel comprises thin films interposed between polarizer layers, wherein at least one of the thin films is a film of vapor deposited wide bandgap semiconductor material extending in distinct columns from a substrate to form a birefringent compensator, which may also act as a liquid crystal alignment layer. The thin films may be transparent and electrically conductive. A liquid crystal layer is interposed between the two thin films. A voltage source is connected to the thin films to apply an electric field across the liquid crystal layer. The birefringent compensator may be one of a positive c-plate, a positive o-plate, and a biaxial plate. The liquid crystals align in one of a homogeneous alignment, heterogeneous alignment, chiral alignment and combinations thereof.

According to another embodiment, there is provided a method of forming a thin film micro structure. The method comprising the step of vapor depositing a wide bandgap semiconductor material, such as a transparent conductive oxide, on a substrate to form a film extending in distinct columns from the substrate. According to another embodiment, the method comprises the step of forming a film on a substrate by depositing a wide bandgap semiconductor material, such as a transparent conductive oxide, by oblique physical vapor deposition. The film may be transparent, electrically conductive and birefringent. Depositing a transparent conductive oxide may comprise vapor depositing a metal-doped oxide, the oxide being selected from a group consisting of: In₂O₃, SnO₂, ZnO, Ga₂O₃, CdO, and combinations thereof. Vapor depositing a wide bandgap semiconductor material may comprise depositing the wide bandgap semiconductor material at an angle within 10° of the angle yielding the maximum birefringence, or at an angle between 20° and 89°, the angle being from the normal of the substrate on which the thin film is formed. Forming a film extending in distinct columns may comprise forming vertical posts, leaning posts, vertical fan-like plates, leaning fan-like plates, helical structures, leaning helical structures, square spirals, chevrons, C-shapes, S-shapes, or columns where the physical cross-section varies in size. Forming a film extending in distinct columns may comprise forming a columnar structure having three principal indices of refraction, wherein the index of refraction is largest in a direction parallel to a central axis of the distinct columns. Vapor depositing a wide bandgap semiconductor material may comprise moving the substrate relative to a source of vapor based on an in situ substrate motion algorithm, the substrate motion algorithm comprising maintaining the substrate stationary, rotating the substrate at predetermined time intervals, or rotating the substrate continuously. Vapor depositing a wide bandgap semiconductor material comprises forming multiple layers of films, each layer being deposited using a different in situ substrate motion algorithm.

These and other aspects are set out in the claims, which are incorporated here by reference.

### BRIEF DESCRIPTION OF THE FIGURES

Preferred embodiments will now be described with reference to the figures, in which like reference characters denote like elements, by way of example, and in which:

FIG. 1a is a schematic side elevation view of a thin film obliquely deposited at an angle of 85°;

FIG. 1b is a schematic front elevation view of the thin film in FIG. 1a;

FIG. 1c is a schematic top plan view of the thin film in FIG. 1a;

FIG. 2a is a schematic side elevation view of a thin film obliquely deposited at an angle of 60°;

FIG. 2b is a schematic front elevation view of the thin film in FIG. 2a;

FIG. 2c is a schematic top plan view of the thin film in FIG. 2a;

FIG. 3 is a graph showing the in plane birefringence of ITO thin films deposited at different angles and annealed at different temperatures;

FIG. 4 is a graph showing the resistivity of ITO thin films deposited at different angles;

FIG. 5 is a graph showing the dependence of transmittance of biregringent ITO thin films deposited onto glass substrates at various deposition angles;

FIG. 6 is a side view of a post of a positive c-plate; and

FIG. 7 is a side view of a leaning post of a positive o-plate.

FIG. 8a is an exploded simplified view of the operation of a liquid crystal display with no applied electric field, where the conventional electrodes, alignment layers, and compensators have been replaced by a single thin film layer.

FIG. 8b is an exploded simplified view of the operation of a liquid crystal display shown in FIG. 8a with an applied electric field.

FIG. 9 is a schematic of a liquid crystal display, take in cross-section, where the conventional electrodes, alignment layers, and compensators have been replaced by a single thin film layer.

FIG. 10 is a simplified schematic of a organic liquid emitting diode display, taken in cross section.

### DETAILED DESCRIPTION OF PREFERRED EMBODIMENTS

By depositing a wide-bandgap material using oblique thin-film deposition techniques, a thin film is created that is transparent, conductive, form-birefringent, and can be used to anchor the alignment of liquid crystals (LCs) near the thin film surface in a liquid crystal display (LCD). A form-birefringent material is one where the birefringence is due to a microstructural anisotropy.

Materials that are both conductive and transparent to visible light are most commonly wide bandgap semiconductors, otherwise known as transparent conducting oxides (TCOs). If the bandgap is not wide enough, the material will absorb visible light at energies that are greater than or equal to the bandgap energy. A material must have a bandgap that exceeds 3 eV to be transparent to visible light. When appropriately doped, the family or ‘phase space’ of possible TCOs includes In₂O₃, SnO₂, ZnO, Ga₂O₃, and CdO. There are 10 binary, 10 ternary, five quaternary, and one quintinary combinations of these five oxides. A common material used in the industry to create conductive, transparent electrodes, and the material used in the exemplary embodiment described below, is tin doped indium oxide (ITO), however, those skilled in the art will understand that other suitable materials may be substituted, such as zinc oxide doped with aluminum (ZnO:Al).

One of the deposition techniques used involves placing the substrate at an angle α to an incident vapor flux to be deposited (in this case, ITO), and keeping the substrate stationary. One acceptable method of oblique deposition is discussed in U.S. Pat. No. 5,866,204, at col. 4, lines 3 to 51. Atomic shadowing causes a columnar microstructure to be formed at an angle β to a perpendicular to the substrate, with the columns forming a fan-like structure in the x-direction. As a result, for ITO, the columnar structure that is formed with no substrate motion will exhibit a fan-like structure which is form-birefringent and biaxial in nature, having three principal indices of refraction. The largest principal refractive index is along the central column axis, the intermediate principal refractive index is perpendicular to the column axis and parallel to the substrate, and the smallest principal refractive index is perpendicular to both of the larger principal indices of refraction.

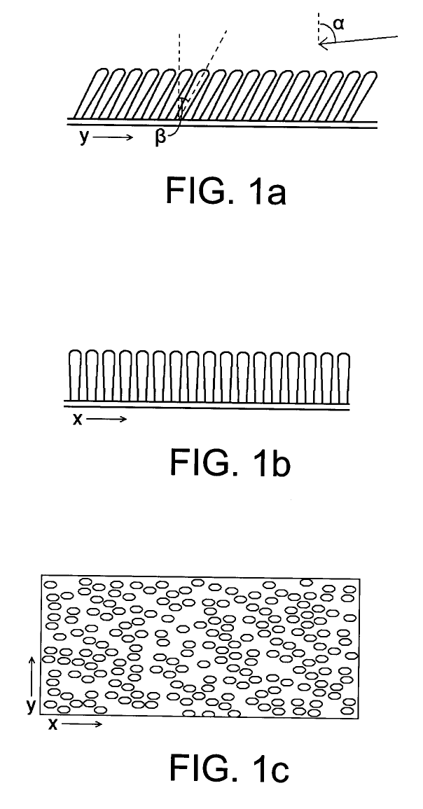

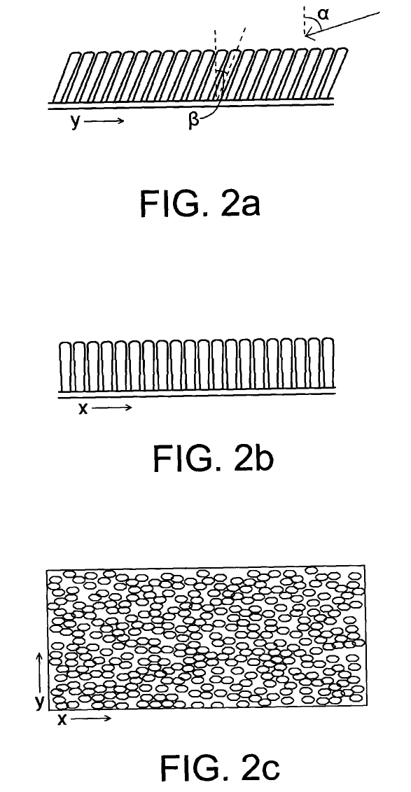

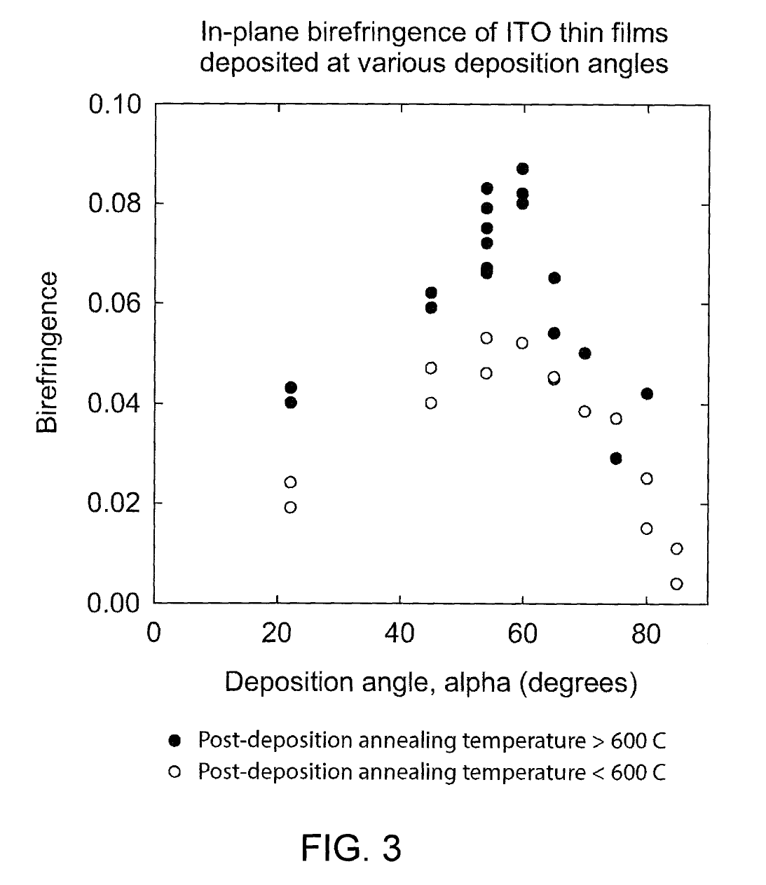

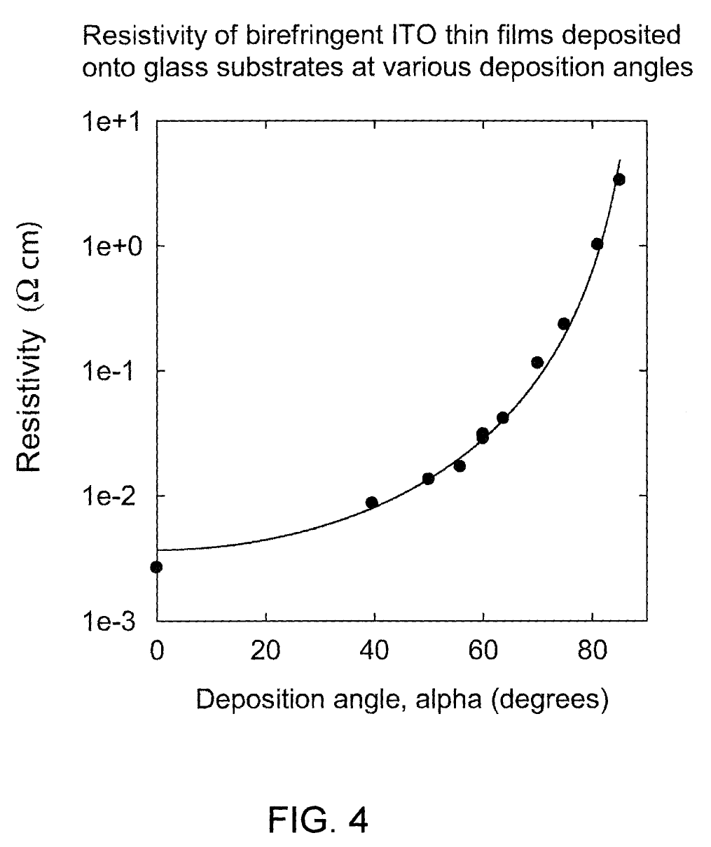

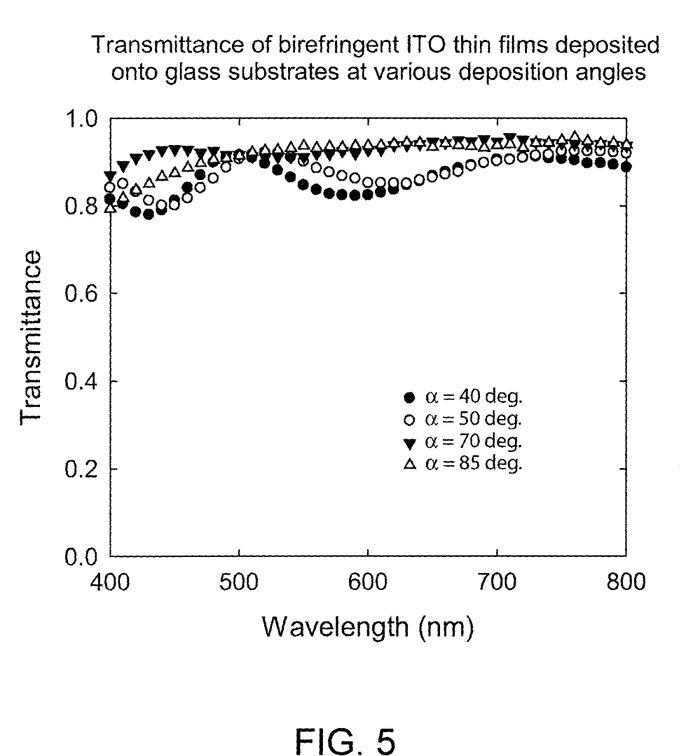

The structure of a thin film can be controlled to a certain extent by adjusting α. Referring to FIGS. 1 and 2, it can be seen that in general, a greater α, represented in FIGS. 1a-1c with α=75°, will result in a structure with a greater β, that is more porous, while a lower α, represented in FIGS. 2a-2c with α=60°, will result in a structure with a lower β that is more dense. It can be seen that, as α and, correspondingly, β increase, the porosity increases, and the difference between the density in the x direction and the y-direction also increases. It will be noted that in FIGS. 1c and 2c, the cross-section of each post is shown as an oval, while in reality the cross-section has a slight concave surface on the bottom. It will be also noted that, while FIGS. 1a, 1b, 2a and 2b show a relatively uniform distribution, this is for illustrative purposes, and may not be the case in practice. The differences in the structures deposited at different angles are primarily due to the fact that atomic shadowing plays a larger role at higher deposition angles, resulting in a more anisotropic structure, and the columns chain together more. The properties that are impacted the most with a changing α are conductivity and birefringence. The relationship between transmittance and deposition angle at various wavelengths of light can be seen referring to FIG. 5. It has been found that transparency remains relatively constant until α exceeds approximately 80° whereupon the thickness of the film has a greater impact upon the transparency. this is due to atomic substrate shadowing, which causes a significant separation between neighboring columnar structures within the thin film matrix. When column separation occurs the proliferation of interfaces between the film material and surrounding void regions can cause substantial diffuse scattering, which reduces the transparency of the thin film layer. Referring to FIG. 4, the relation between resistivity and α is shown. As expected, resistivity increases with a greater α because of the increased porosity, however the resistivity is still relatively low around 60°. A possible method of decreasing resistivity is to form the thin film layer onto another dense TCO layer deposited at near-normal incidence. With respect to the form-birefringence exhibited by a single columnar thin film layer, as the deposition angle is increased from normal incidence, the anisotropic atomic-shadowing increases which results in an enhanced form-birefringence. However, as the deposition angle increases, the film density monotonically decreases. The effective refractive index of the thin film layer is a result of contributions of the solid film material and the porous regions between the columnar structures. As the number and size of the pores increase, their contribution to the film's effective refractive index also increases, which tends to lower the effective index since the pores are most often filled with air. Because the form-birefringence scales with the average refractive index of the thin film layer, the form-birefringence will decrease as the porosity of the thin film increases. The two competing effects, increased structural anisotropy and a decreased effective refractive index, results in a maximum in form-birefringence at an intermediate deposition angle; in the case of FIG. 3, this maximum is observed at a deposition angle of α=60°. It has been determined that acceptable results for the thin film generally can be achieved in the range 20°<α<70°. The birefringence obtained is greater than Δn=0.05.

Whereas the leaning fan-like plates described above are formed by holding the substrate stationary during oblique physical vapor deposition, the columnar structures described as vertical posts, leaning posts, vertical fan-like plates, helical structures, and leaning helical structures are formed by in situ substrate motion. For example, during deposition, the substrate may be rotated at a constant angular velocity to form either a helical structure if the rotation is slow enough, or a post structure with a circular cross-section if the substrate is rotated faster. The porosity of these structures is also dependent upon the deposition angle, with the proprsity generally increasing with a greater deposition angle. Forming a helical structure is discussed in U.S. Pat. No. 5,866,204 starting at col. 4, line 52. Alternatively, a leaning post structure with a circular cross-section (as opposed to the fan structure above) may be formed by using a spin-pause technique as described in U.S. Pat. No. 6,206,065, where the rotation is slowed for a part of the rotation. Another technique involves rotating the substrate by 90° or 180° increments to form a square chiral or zig-zag structure, respectively. A rapid zig-zag structure will degenerate into a thin film layer composed of vertical fan-like shapes, which exhibit the largest form-birefringence in the plane of the substrate amongst the various columnar structure types. The thin film layer may therefore have a columnar structure such as vertical posts, leaning posts, vertical fan-like plates, leaning fan-like plates, helical structures, leaning helical structures, square spirals, chevrons, C-shapes, S-shapes, and columns where the physical cross-section varies in size. Each group of columnar structures is formed by combining oblique physical vapor deposition with an appropriate in situ substrate motion algorithm. The thin film may also have a plurality of layers by employing a sequential series of substrate motion algorithms to form a thin film wherein the type of columnar structure changes with each layer, the principal indices of refraction have a different orientation, or a combination of these layers.

While some of the deposition techniques discussed previously result in a biaxial material, other techniques may be used to obtain a uniaxial material, wherein two of the three principal indices of refraction are equal in magnitude and denoted the ordinary index of refraction (nₒ), while the third principal refractive index is typically aligned parallel to the central axis of the thin film columns, and is denoted the extraordinary index of refraction (nₑ).

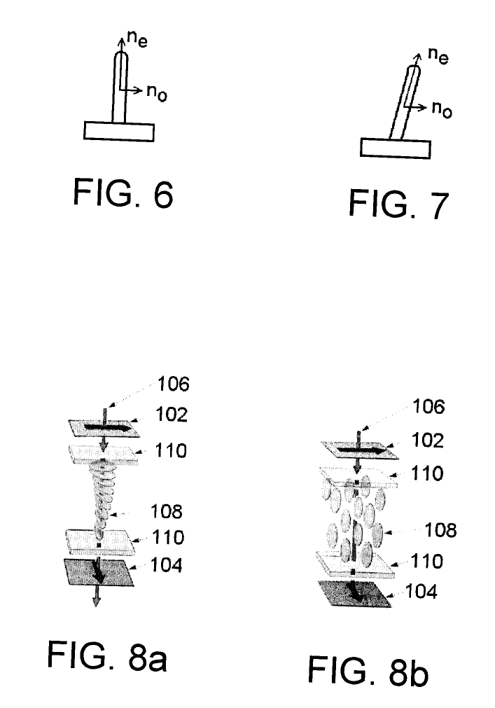

A positive c-plate, shown in FIG. 6, where nₑ>nₒ, can be formed by rotating the substrate uniformly. It is believed on reasonable grounds that a positive o-plate, shown in FIG. 7, where nₑ>nₒ, may be obtained from a leaning post formed using the spin-pause technique.

Once the thin film has been deposited on the substrate, if it is not already made sufficiently conductive and transparent during the deposition process, it is necessary to treat the thin film after completing the physical vapor deposition step. Post-deposition treatment of obliquely deposited columnar layers may be used to improve conductivity or transparency. In a specific example, post-deposition annealing was undertaken in air at a temperature of between 400-500° C.

By using form-birefringent ITO, it is believed on reasonable grounds that the function of the compensators can be integrated into the ITO layer of flat panel displays, eliminating the need to use some or all of the organic birefringent films currently used in LCDs. In this case, the birefringent compensator is a thin film layer having positive refractive index anisotropy, where the principal optical axis is aligned in a direction parallel to the substrate normal, in the case of a positive c-plate, or in a direction that forms an oblique angle with the substrate normal, in the case of a positive o-plate. The compensator may also be biaxial. A combination of thin film layers having various columnar structures, thicknesses, orientations, and porosities may be used and optimized depending on the liquid crystal display configuration and the viewing angle characteristics to be improved.

With respect to LC alignment, as with obliquely-deposited silicon oxide, TCOs are capable of aligning LCs such that their alignment is related to the orientation and nature of the microstructural columns. Preferred alignment directions vary with changes in a and TCO material, but in general, there is a range of deposition angles between approximately 70°<α<89°, in which LCs will align along the column axis, and another range between approximately 30°<α<70°, in which LCs will align along the x-direction. Liquid crystals that are located within close proximity to the outer interface of the thin film layer form homogeneous, heterogeneous, or chiral alignments, or an intermediate alignment depending on the type of thin film columnar structure. This ability to align LCs is very beneficial because it makes it possible to integrate another function into the form-birefringent ITO layer, eliminating the need for polymer alignment layers, which allows another component of an LCD display to be combined into the ITO layer.

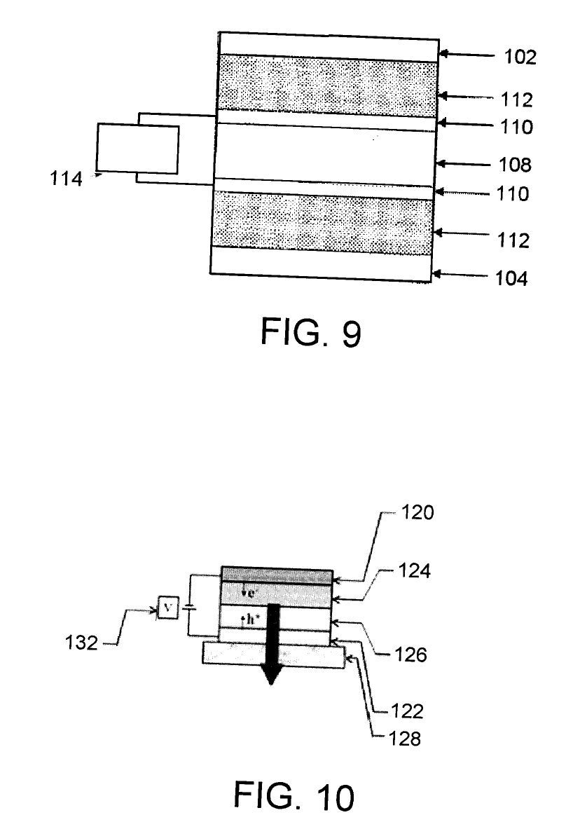

As mentioned above, one potential use of the thin film is with LCDs. Many LCD configurations are possible, and will depend on the specific implementation. An illustrative embodiment of a LCD is schematically represented by the cross-sections shown in FIGS. 8a, 8b and 9. Referring to FIG. 8a, in a normally-white display, the transmission axis of the polarizer 102 and analyzer 104 are at 90° to one another. Light 106 that is incident upon the polarizer 102 is subsequently rotated by 90° as it passes through the liquid crystal layer 108 and is transmitted by the analyzer 104. Referring to FIG. 9, the thin film layer 110 described above is shown on a glass substrate 112, and acts as a birefringent compensator, a liquid crystal alignment layer, and a transparent electrode. When a voltage is applied to the thin films 110 acting as electrodes by circuitry 114, the liquid crystals 108 align with the electric field as shown in FIG. 8b, and the display goes from the white-state to the black-state. Without an applied voltage, the liquid crystals 108 are aligned in a twisted nematic configuration as shown in FIG. 8a by the thin films 110 acting as alignment layers, which must be oriented 90° to another. The thin film layer 110 also compensates for the difference in phase shifts experienced by linearly polarized light as it travels at oblique angles through the display. When properly designed by those skilled in the art, the thin film 110 acting as a compensator will improve contrast and gray-scale stability at wide viewing angles. Alternatively, the thin film 110 layer may act as a compensator and a transparent electrode only, while a conventional rubbed polyimide layer (not shown) is used to achieve liquid crystal alignment. In this case, the polyimide layer appears on either side of the liquid crystals, and the thin film layer 110 appears between the polyimide and the glass substrate.

It will be understood that the above description is only one possible configuration of a liquid crystal display, and is simplified. State of the art displays utilize many more layers, including those necessary to achieve active-matrix addressing, color pixels, barriers to diffusion, passivation, and lighting distribution. In addition, the thin film layer need not be used in the split design shown below. The thin film layer may appear on only one of the substrates, and may be used in combination with additional compensators to improve viewing angle characteristics. As a general rule, the thin film layer replaces the conventional transparent electrode in most liquid crystal display configurations.

Another example of a potential use involves a new class of emerging displays that are based on organic light emitting diodes (OLED). A simplified structure is shown in FIG. 10, where carbon-based films are sandwiched between a charged metallic cathode 120 and a charged transparent anode 122, such as ITO. The organic films consists of an electron transport combined with an emissive layer 124 and a hole-transport layer 126. When voltage 132 is applied to the OLED cell, the injected positive and negative charges recombine in the emissive layer and create electro-luminescent light which escapes through the transparent substrate 128. Unlike LCDs, which require backlighting, OLED displays emit light rather than modulate transmitted or reflected light. A method used to enhance the contrast of an OLED in ambient light is to use circular polarization filters. A circular polarization filter is formed by the combination of a linear polarizer and a quarter-wave plate. A quarter-wave plate is formed by one or more birefringent thin films. OLED displays also use ITO films as transparent electrodes. As with LCDs, the birefringent quarter-wave plate can be combined with the transparent electrode into a single thin-film layer. This simplifies the design and reduces the manufacturing cost of the display, especially when the birefringent ITO technology is combined with coated polarizer technology.

Another opportunity for these films is in the Liquid Crystal on Silicon (LCOS) technology used for rear and front projection displays. LCOS is a reflective technology that uses liquid crystals applied to a reflective mirror substrate. The liquid crystals act as a light-valve in a fashion similar to the LCD described above, the light is either reflected from the mirror below, or blocked to modulate the light and create an image. These specially designed LCDs switch very quickly and can be produced in line with traditional semiconductor facilities. When used in a projection system, the LCOS displays are subjected to very high light intensities that have the tendency to degrade traditional organic films. For this reason, wire grid polarizers are used in place of drawn polymers. In order to improve the contrast ratio (values in excess of 400 are required to make projection LCDs feasible) films must be added with a small retardance, typically ˜20 nm. Since organic retarders degrade, the ITO films provide a much more stable replacement. Also, with LCOS, the polyimide liquid crystal orientation layers are subjected to a photochemical degradation with high intensity light exposure. Since the ITO films also orient LCs and are resistant to photochemical breakdown, this degradation may be avoided.

In general, applications which require or benefit from both birefringent thin films and transparent conductive layers may utilize this technology. Besides the various flat panel displays mentioned above, an additional application may be in optical coatings or bulk optics. Wave plates, also known as retarders or compensators, are used to produce a specific phase shift between linearly polarized light that is incident along the wave plate's slow and fast axis. Often produced by bulk crystal optics, the same phase shift can be created by a birefringent thin film. If that film is conductive, the optic will accumulate less static charge and fewer dust particles will land on the surface of optic. Dust-free optics are important in applications such as fiber optics, where a small beam of light is easily scattered by dust.

Immaterial modifications may be made to the embodiments described here without departing from what is covered by the claims.

What is claimed is:

1. A thin film microstructure, comprising:
a substrate; and
a film of vapor deposited wide bandgap semiconductor material extending in distinct columns from the substrate.

2. The thin film microstructure of claim 1, wherein the film is transparent, electrically conductive, and birefringent.

3. The thin film microstructure of claim 1, wherein the film is porous.

4. The thin film microstructure of claim 1, wherein the wide bandgap semiconductor material is a transparent conductive oxide.

5. The thin film microstructure of claim 4, wherein the transparent conductive oxide is a metal-doped oxide selected from a group consisting of: In₂O₃, SnO₂, ZnO, Ga₂O₃, CdO, and combinations thereof.

6. The thin film microstructure of claim 1, wherein the wide bandgap semiconductor material is deposited at an angle within 10° of the angle yielding the maximum birefringence, the angle being from the normal of the substrate on which the thin film is formed.

7. The thin film microstructure of claim 1, wherein the wide bandgap semiconductor material is vapor deposited at an angle between 20° and 89° from the normal of the substrate on which the thin film is formed.

8. The thin film microstructure of claim 1, wherein the distinct columns comprise vertical posts, leaning posts, vertical fan-like plates, leaning fan-like plates, helical structures, leaning helical structures, square spirals, chevrons, C-shapes, S-shapes, or columns where the physical cross-section varies in size.

9. The thin film microstructure of claim 8, wherein the distinct columns have three principal indices of refraction, wherein the index of refraction is largest in a direction parallel to a central axis of the distinct columns.

10. The thin film microstructure of claim 1, wherein the film comprises multiple layers of distinct columns.

11. The thin film microstructure of claim 1, in combination with carbon-based films and an electrode to form an organic light emitting diode.

12. The thin film microstructure of claim 1, in combination with a liquid crystal layer and a reflective substrate to form a liquid crystal on silicon display.

13. A liquid crystal display comprising:
thin films interposed between polarizer layers, wherein at least one of the thin films is a film of vapor deposited wide bandgap semiconductor material extending in distinct columns from a substrate to form a birefringent compensator, the thin films being transparent, electrically conductive;
a liquid crystal layer interposed between the two thin films; and
a voltage source connected to the thin films to apply an electric field across the liquid crystal layer.

14. The liquid crystal display of claim 13, wherein the birefringent compensator is one of a positive c-plate, a positive o-plate, and a biaxial plate.

15. The liquid crystal display of claim 13, wherein the film of vapor deposited wide bandgap semiconductor material acts as a liquid crystal alignment layer.

16. The liquid crystal display of claim 15, wherein liquid crystals align in one of: a homogeneous alignment, heterogeneous alignment, chiral alignment and combinations thereof.

17. A pixel of a liquid crystal display comprising:
thin films interposed between two polarizer layers, wherein at least one of the thin films is a film of vapor deposited wide bandgap semiconductor material extending in distinct columns from a substrate to form a birefringent compensator, the thin films being transparent and electrically conductive;
a liquid crystal layer interposed between the two thin films; and
a voltage source connected to the thin films to apply an electric field across the liquid crystal layer.

18. A method of forming a thin film micro structure, the method comprising the step of:
vapor depositing a wide bandgap semiconductor material on a substrate to form a film extending in distinct columns from the substrate.

19. The method of claim 18, wherein the film is transparent, electrically conductive, and birefringent.

20. The method of claim 18, wherein the film is porous.

21. The method of claim 18, wherein vapor depositing a wide bandgap semiconductor material comprises depositing a transparent conductive oxide.

22. The method of claim 21, wherein vapor depositing a transparent conductive oxide comprises vapor depositing a metal-doped oxide, the oxide being selected from a group consisting of: In₂O₃, SnO₂, ZnO, Ga₂O₃, CdO, and combinations thereof.

23. The method of claim 18, wherein vapor depositing a wide bandgap semiconductor material comprises depositing the wide bandgap semiconductor material at an angle within 10° of the angle yielding the maximum birefringence, the angle being from the normal of the substrate on which the thin film is formed.

24. The method of claim 18, wherein vapor depositing a wide bandgap semiconductor material comprises depositing the wide bandgap semiconductor material at an angle between 20° and 89° from the normal of the substrate on which the thin film is formed.

25. The method of claim 18, wherein forming a film extending in distinct columns comprises forming vertical posts, leaning posts, vertical fan-like plates, leaning fan-like plates, helical structures, leaning helical structures, square spirals, chevrons, C-shapes, S-shapes, or columns where the physical cross-section varies in size.

26. The method of claim 18, wherein forming a film extending in distinct columns comprises forming a columnar structure having three principal indices of refraction, wherein the index of refraction is largest in a direction parallel to a central axis of the distinct columns.

27. The method of claim 18, wherein vapor depositing a wide bandgap semiconductor material comprises moving the substrate relative to a source of vapor based on an in situ substrate motion algorithm, the substrate motion algorithm comprising maintaining the substrate stationary, rotating the substrate at predetermined time intervals, or rotating the substrate continuously.

28. The method of claim 26, wherein vapor depositing a wide bandgap semiconductor material comprises forming multiple layers of films, each layer being deposited using a different in situ substrate motion algorithm.

29. A thin film microstructure, comprising:
a film of oblique physical vapor deposited wide bandgap semiconductor material on a substrate, the film being transparent, electrically conductive, and birefringent.

30. The thin film microstructure of claim 29, wherein the wide bandgap semiconductor material is a transparent conductive oxide.

31. The thin film microstructure of claim 30, wherein the transparent conductive oxide is a metal-doped oxide, the oxide being selected from a group consisting of: In₂O₃, SnO₂, ZnO, Ga₂O₃, CdO, and combinations thereof.

32. The thin film microstructure of claim 29, wherein the wide bandgap semiconductor material is deposited at an angle within 10° of the angle yielding the maximum birefringence, the angle being from the normal of the substrate on which the thin film is formed.

33. The thin film microstructure of claim 29, wherein the wide bandgap semiconductor material is vapor deposited at an angle between 20° and 89° from the normal of the substrate on which the thin film is formed.

34. The thin film microstructure of claim 29, wherein the film comprises distinct columns of vertical posts, leaning posts, vertical fan-like plates, leaning fan-like plates, helical structures, leaning helical structures, square spirals, chevrons, C-shapes, S-shapes, or columns where the physical cross-section varies in size.

35. The thin film microstructure of claim 34, wherein the distinct columns have three principal indices of refraction, wherein the index of refraction is largest in a direction parallel to a central axis of the distinct columns.

36. The thin film microstructure of claim 29, wherein the film comprises multiple layers of distinct columns.

37. A method of forming a thin film microstructure, the method comprising the step of:
forming a film on a substrate by depositing a wide bandgap semiconductor material by oblique physical vapor deposition, the film being transparent, electrically conductive and birefringent.

38. The method of claim 37, wherein depositing a wide bandgap semiconductor material comprises depositing a transparent conductive oxide.

39. The method of claim 38, wherein depositing a transparent conductive oxide comprises vapor depositing a metal-doped oxide, the oxide being selected from a group consisting of: In₂O₃, SnO₂, ZnO, Ga₂O₃, CdO, and combinations thereof.

40. The method of claim 37, wherein depositing a wide bandgap semiconductor material comprises depositing the wide bandgap semiconductor material at an angle within 10° of the angle yielding the maximum birefringence, the angle being from the normal of the substrate on which the thin film is formed.

41. The method of claim 37, wherein depositing a wide bandgap semiconductor material comprises depositing the wide bandgap semiconductor material at an angle between 20° and 89° from the normal of the substrate on which the thin film is formed.

42. The method of claim 37, wherein forming a film comprises forming a film extending in distinct columns, the distinct columns comprising vertical posts, leaning posts, vertical fan-like plates, leaning fan-like plates, helical structures, leaning helical structures, square spirals, chevrons, C-shapes, S-shapes, or columns where the physical cross-section varies in size.

43. The method of claim 42, wherein forming a film extending in distinct columns comprises forming a columnar structure having three principal indices of refraction, wherein the index of refraction is largest in a direction parallel to a central axis of the distinct columns.

44. The method of claim 37, wherein depositing a wide bandgap semiconductor material comprises moving the substrate relative to a source of vapor based on an in situ substrate motion algorithm, the substrate motion algorithm comprising maintaining the substrate stationary, rotating the substrate at predetermined time intervals, or rotating the substrate continuously.

45. The method of claim 44, wherein depositing a wide bandgap semiconductor material comprises forming multiple layers of films, each layer being deposited using a different in situ substrate motion algorithm.
